(19) United States
(12) Patent Application Publication
(10) Pub. No.: US 2024/0304663 A1
(43) Pub. Date: Sep. 12, 2024

(54) CAPACITOR STRUCTURE AND SEMICONDUCTOR DEVICE INCLUDING THE CAPACITOR STRUCTURE

(71) Applicant: SAMSUNG ELECTRONICS CO., LTD., Suwon-si (KR)

(72) Inventors: Chunhum CHO, Suwon-si (KR); Sunmin MOON, Suwon-si (KR); Dongkwan BAEK, Suwon-si (KR); Jaewan CHANG, Suwon-si (KR)

(21) Appl. No.: 18/417,150

(22) Filed: Jan. 19, 2024

(30) Foreign Application Priority Data
Mar. 6, 2023 (KR) 10-2023-0028947
Sep. 11, 2023 (KR) 10-2023-0120300

(51) Int. Cl. H01G 4/33; H10B 12/00

(52) U.S. Cl. CPC H01L 28/91; H10B 12/033

(57) ABSTRACT

The capacitor structure includes a lower electrode on a substrate; a support layer on a sidewall of the lower electrode, the support layer including an insulating material; an interface structure having a first interface pattern on the sidewall of the lower electrode, the first interface pattern including a first metal, and a second interface pattern including a first portion on an outer sidewall of the first interface pattern and a second portion on a surface of the support layer, the second interface pattern including an oxide of a second metal, a dielectric pattern on the interface structure; and an upper electrode on the dielectric pattern, wherein the second portion of the second interface pattern further includes the first metal.

### CROSS-REFERENCE TO RELATED APPLICATION

This application claims priority under 35 U.S.C. § 119 to Korean Patent Application No. 10-2023-0028947, filed on Mar. 6, 2023, and Application No. 10-2023-0120300, filed on Sep. 11, 2023, in the Korean Intellectual Property Office, the disclosure of which is hereby incorporated by reference in its entirety.

### BACKGROUND

### 1. Field

Example embodiments of the present disclosure relate to a capacitor structure and a semiconductor device including the capacitor structure.

### 2. Description of the Related Art

A capacitor structure included in a dynamic random access memory (DRAM) device may include a capacitor having a lower electrode, a dielectric layer, and an upper electrode sequentially stacked, and support layers each of which may contact a surface of the lower electrode and be spaced apart from each other in a vertical direction. An interface layer, which may be conductive, may be additionally disposed between the lower electrode and the dielectric layer.

### SUMMARY

According to example embodiments, there is provided a capacitor structure. The capacitor structure may include a lower electrode on a substrate; a support layer on a sidewall of the lower electrode, the support layer including an insulating material; an interface structure on the lower electrode; a dielectric pattern on the interface structure; and an upper electrode on the dielectric pattern. The interface structure may include a first interface pattern on the sidewall of the lower electrode, the first interface pattern including a first metal; and a second interface pattern on the first interface pattern and including an oxide of a second metal, the second interface pattern including a first portion on an outer sidewall of the first interface pattern and a second portion extending from the first portion along a surface of the support layer, and the second portion including the first metal.

According to example embodiments, there is provided a capacitor structure. The capacitor structure may include a lower electrode on a substrate; a support layer on a sidewall of the lower electrode, the support layer including an insulating material; an interface structure on the lower electrode; a dielectric pattern on the interface structure; and an upper electrode on the dielectric pattern. The interface structure may include: a first interface pattern on the sidewall of the lower electrode, the first interface pattern including an oxide of a first metal; and a second interface pattern on the first interface pattern and including an oxide of a second metal, the second interface pattern including a first portion on an outer sidewall of the first interface pattern and a second portion extending from the first portion along a surface of the support layer, wherein a thickness a vertical direction of the second portion of the second interface pattern is greater than a thickness in a horizontal direction of the first portion of the second interface pattern, the vertical direction being substantially perpendicular to an upper surface of the substrate, and the horizontal direction being substantially parallel to the upper surface of the substrate.

According to example embodiments, there is provided a semiconductor device. The semiconductor device may include an active pattern on a substrate; a gate structure in an upper portion of the active pattern, the gate structure extending in a first direction substantially parallel to an upper surface of the substrate; a bit line structure on a middle portion of the active pattern, the bit line structure extending in a second direction substantially parallel to the upper surface of the substrate and crossing the first direction; a contact plug structure on each of opposite ends of the active pattern; and a capacitor structure on the contact plug structure. The capacitor structure may include: a lower electrode on the substrate, a support layer on a sidewall of the lower electrode, the support layer including an insulating material; an interface structure; a dielectric pattern on the interface structure, and an upper electrode on the dielectric pattern. The interface structure may include a first interface pattern on the sidewall of the lower electrode, the first interface pattern including a first metal, and a second interface pattern including a first portion on an outer sidewall of the first interface pattern and a second portion on a surface of the support layer, the second interface pattern including an oxide of a second metal, and the second portion of the second interface pattern further including the first metal.

### BRIEF DESCRIPTION OF THE DRAWINGS

Features will become apparent to those of skill in the art by describing in detail exemplary embodiments with reference to the attached drawings, in which

FIG. 1 is a cross-sectional view illustrating a first capacitor structure according to example embodiments.

FIG. 2 is an enlarged cross-sectional view of region X of FIG. 1.

FIGS. 3 to 12 are cross-sectional views illustrating stages in a method of forming a first capacitor structure in accordance with example embodiments.

FIG. 13 is a cross-sectional view illustrating a second capacitor structure in accordance with example embodiments.

FIG. 14 is a plan view illustrating a semiconductor device in accordance with example embodiments.

FIG. 15 is a cross-sectional view taken along line A-A′ of FIG. 14.

FIGS. 16 to 31 are plan views and cross-sectional views illustrating stages in a method of manufacturing a semiconductor device according to example embodiments.

### DETAILED DESCRIPTION

The above and other aspects and features of the capacitor structures and the methods of manufacturing the same, the semiconductor devices including the capacitor structures and the methods of manufacturing the same in accordance with example embodiments will become readily understood from detailed descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

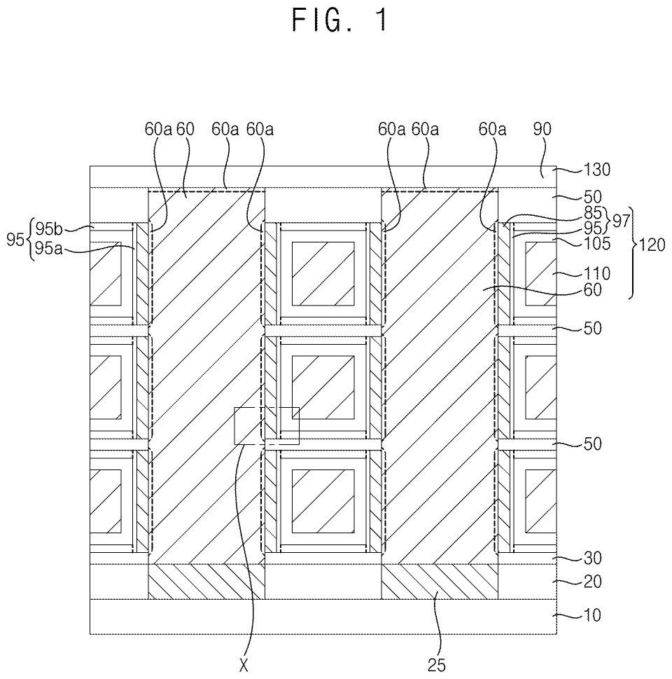

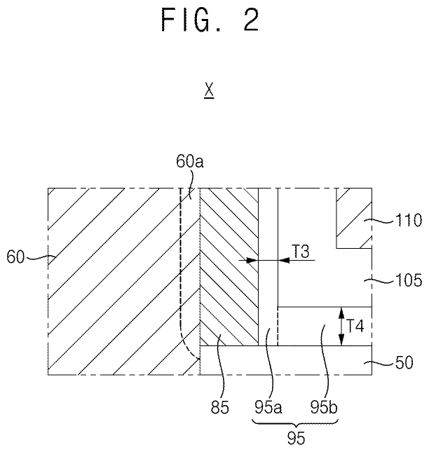

FIG. 1 is a cross-sectional view illustrating a first capacitor structure according to example embodiments, and FIG. 2 is an enlarged cross-sectional view of region X of FIG. 1.

Referring to FIGS. 1 and 2, the first capacitor structure may include a first capacitor 120, a support layer 50, and an upper electrode plate 130 on a substrate 10. The first capacitor 120 may include a lower electrode 60, an interface structure 97 having a first interface pattern 85 and a second interface pattern 95, a dielectric pattern 105, and an upper electrode 110. The first capacitor structure may further include a first conductive pattern 25 contacting an upper surface of the lower electrode 60, a first insulating interlayer 20 containing the first conductive pattern 25, and a first etch stop layer 30 on the substrate 10.

The substrate 10 may include silicon, germanium, silicon-germanium, or a III-V group compound semiconductor, e.g., GaP, GaAs, or GaSb. In example embodiments, the substrate 10 may be a silicon-on-insulator (SOI) substrate or a germanium-on-insulator (GOI) substrate.

The first conductive pattern 25 may include, e.g., contact plugs, landing pads, etc., and a plurality of first conductive patterns 25 may be spaced apart from each other in a horizontal direction substantially parallel to an upper surface of the substrate 10. The first insulating interlayer 20 may include an oxide, e.g., silicon oxide or a low-k dielectric material, and the first conductive pattern 25 may include, e.g., a metal, a metal nitride, a metal silicide, doped polysilicon, etc.

The first etch stop layer 30 may be formed on the first insulating interlayer 20. The first etch stop layer 30 may include an insulating nitride, e.g., silicon nitride, silicon boronitride, silicon carbonitride, etc.

In example embodiments, the first etch stop layer 30 may further include a first metal. The first metal may include, e.g., scandium (Sc), yttrium (Y), titanium (Ti), vanadium (V), niobium (Nb), tantalum (Ta), chromium (Cr), molybdenum (Mo), tungsten (W), iron (Fe), ruthenium (Ru), osmium (Os), cobalt (Co), rhodium (Rh), iridium (Ir), boron (B), tin (Sn), etc. Additionally, the first etch stop layer 30 may further include a second metal. For example, the second metal may include a metal with four valance electrons, e.g., hafnium, or a metal with three valance electrons, e.g., aluminum.

The lower electrode 60 may extend through the first etch stop layer 30, and may contact an upper surface of a corresponding one of the first conductive patterns 25. For example, the lower electrode 60 may have a shape of a pillar extending in a vertical direction substantially perpendicular to the upper surface of the substrate 10. In another example, the lower electrode 60 may have a shape of a cup or a hollow cylinder. The lower electrode 60 may include, e.g., a metal, a metal nitride, polysilicon doped with impurities, etc.

In example embodiments, a portion of the lower electrode 60 in contact with the interface structure 97 and a portion the lower electrode 60 in contact with the upper electrode plate 130 may be referred to as a doped region 60a (e.g., the doped region 60a is indicated by a dashed line in FIG. 1). The doped region 60a of the lower electrode 60 may further include the first metal, and accordingly, the doped region 60a may have greater conductivity than other portions of the lower electrode 60 excluding the doped region 60a. Therefore, overall conductivity of the lower electrode 60 may increase.

For example, a plurality of doped regions 60a of the lower electrode 60 may be spaced apart from each other in the vertical direction. In another example, the doped regions 60a adjacent to each other in the vertical directions may be merged and connected to each other.

The support layer 50 may be formed on a sidewall of each of the lower electrode 60, and may have a shape of a plate having lower and upper surfaces substantially parallel to the upper surface of the substrate 10. In example embodiments, a plurality of support layers 50 may be spaced apart from each other in the vertical direction substantially perpendicular to the upper surface of the substrate 10, e.g., the support layers 50 may extend lengthwise perpendicularly to the lower electrode 60.

The support layer 50 may include an insulating nitride, e.g., silicon nitride. However, in example embodiments, the support layer 50 may further partially include the first metal and the second metal.

The interface structure 97 may include the first interface pattern 85 and the second interface pattern 95 sequentially stacked on a sidewall of the lower electrode 60, e.g., stacked on a lateral sidewall of the lower electrode 60 facing the upper electrode 110. For example, as illustrated in FIG. 1, each of the first interface pattern 85 and the second interface pattern 95 may be on (e.g., may directly contact) portions of the lower and upper surfaces of the support layer 50. For example, as further illustrated in FIG. 1, the first interface pattern 85 and the second interface pattern 95 of the interface structure 97 may separate between the lateral sidewall of the lower electrode 60 and a lateral sidewall of the dielectric pattern 105 facing the lower electrode 60.

In detail, the first interface pattern 85 may cover (e.g., may be directly on) the sidewall of the lower electrode 60 and a portion of the surface of the support layer 50 adjacent to the lower electrode 60. In example embodiments, the first interface pattern 85 may include the first metal, an oxide of the first metal or a nitride of the first metal, and thus, may be conductive.

In example embodiments, the first interface pattern 85 may be multi-layered. For example, the first interface pattern 85 may include a titanium oxide layer and a niobium oxide layer sequentially stacked, a niobium oxide layer and a titanium oxide layer sequentially stacked, or a titanium oxide layer, a niobium oxide layer and a titanium oxide layer sequentially stacked.

The second interface pattern 95 may have insulating properties and may include a sixth portion 95b on the surface of the support layer 50 and a seventh portion 95a extending in the vertical direction from the sixth portion 95b and covering an outer sidewall of the first interface pattern 85. For example, as illustrated in FIGS. 1 and 2, the first interface pattern 85 may have a linear structure extending lengthwise along the lateral sidewall of the lower electrode 60, and the sixth and seventh portions 95b and 95a of the second interface pattern 95 may be arranged into a quadrangular frame surrounding the dielectric pattern 105 and the upper electrode 110. In example embodiments, the second interface pattern 95 may include an oxide of the second metal.

In example embodiments, a fourth thickness T4 in the vertical direction of the sixth portion 95b of the second interface pattern 95 may be greater than a third thickness T3 in the horizontal direction of the seventh portion 95a of the second interface pattern 95. In example embodiments, the fourth thickness T4 of the sixth portion 95b of the second interface pattern 95 may be in a range about 0.5 angstroms to about 2 angstroms.

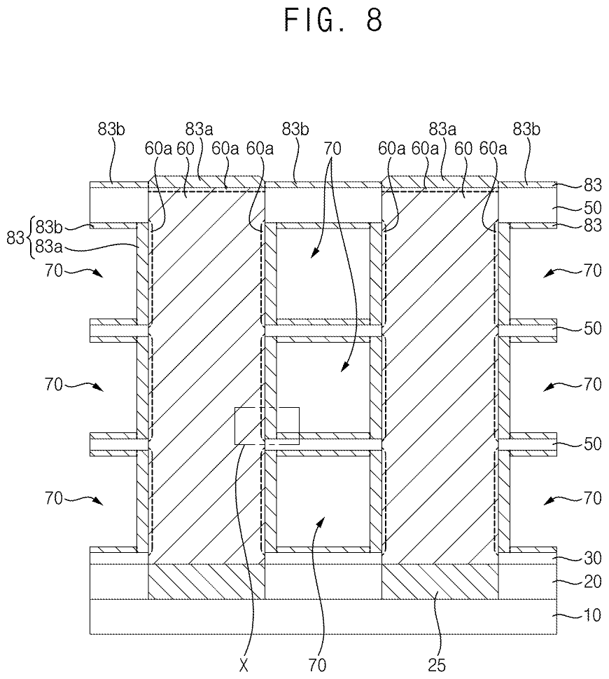

In example embodiments, as described later, the sixth portion 95b of the second interface pattern 95 may merge with the first interface layer 83 remaining on the surface of the support layer 50 (refer to FIGS. 8 to 11). Accordingly, the sixth portion 95b of the second interface pattern 95 may further include the first metal of the first interface layer 83 which may later transform to the first interface pattern 85.

The first metal, an oxide of the first metal, or a nitride of the first metal of the first interface layer 83 may have conductivity. However, the first interface layer 83 may merge with the second interface layer 90 having an oxide of the second metal, and thus, concentration of oxygen vacancy in the second interface layer 90 may decrease. Accordingly, the sixth portion 95b of the second interface pattern 95 may have insulating properties, and leakage current there through may be reduced.

The dielectric pattern 105 may contact (e.g., via the interface structure 97) the sidewall of each of the lower electrodes 60 between the first etch stop layer 30 and a lowermost one of the support layers 50 and between the support layers 50. The dielectric pattern 105 may include a metal oxide. In an example embodiment, the dielectric pattern 105 may include an oxide of, e.g., hafnium, zirconium, or aluminum.

The upper electrode 110 may be formed between the first etch stop layer 30 and the lowermost one of the support layers 50 and between the support layers 50. The upper electrode 110 and the lower electrode 60 may include substantially the same material, or may include different materials.

The upper electrode plate 130 may extend in parallel to the substrate 10 on the tops of the lower electrodes 60. The upper electrode plate 130 may include, e.g., doped silicon-germanium.

As described above, the first capacitor 120 of the first capacitor structure may further include the interface structure 97 disposed between the lower electrode 60 and the dielectric pattern 105, and accordingly, the first capacitor 120 may have increased capacitance. Additionally, the sixth portion 95b of the second interface pattern 95 that is included in the interface structure 97 and disposed on the surfaces of the support layers 50 may have insulating properties, and thus, leakage current may decrease.

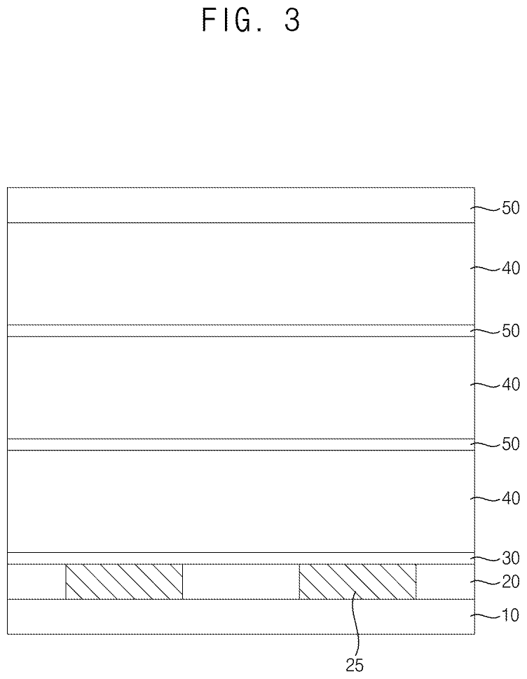

FIGS. 3 to 12 are cross-sectional views illustrating stages in a method of forming a first capacitor structure in accordance with example embodiments.

Referring to FIG. 3, the first insulating interlayer 20 containing the first conductive pattern 25 may be formed on the substrate 10, the first etch stop layer 30 may be formed on the first insulating interlayer 20 and the first conductive pattern 25, and a mold layer 40 and the support layer 50 may be alternately and repeatedly stacked on the first etch stop layer 30. In example embodiments, a plurality of the first conductive patterns 25 may be spaced apart from each other in a horizontal direction substantially parallel to an upper surface of the substrate 10. The mold layer 40 may include an oxide, e.g., silicon oxide or a low-k dielectric material.

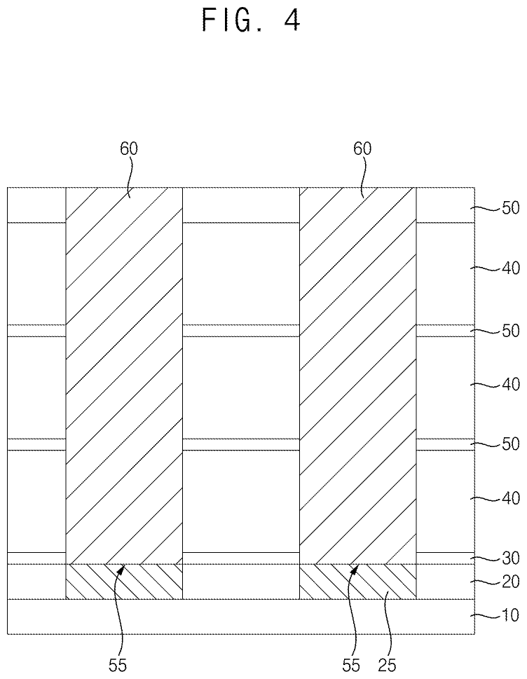

Referring to FIG. 4, a first opening 55 may be formed through the support layer 50, the mold layer 40, and the first etch stop layer 30 to expose an upper surface of each of the first conductive patterns 25. A first lower electrode layer may be formed on the upper surface of the first conductive pattern 25 exposed by the first opening 55, a sidewall of the first opening 55, and an upper surface of an uppermost one of the support layers 50.

In example embodiments, the lower electrode layer may be formed by a deposition process, e.g., an atomic layer deposition (ALD) process, a chemical vapor deposition (CVD) process, etc. The lower electrode layer may be planarized until the upper surface of the uppermost one of the support layers 50 is exposed, and the lower electrode 60 may be formed in each of the first openings 55. The planarization process may include a chemical mechanical polishing (CMP) process and/or an etch back process.

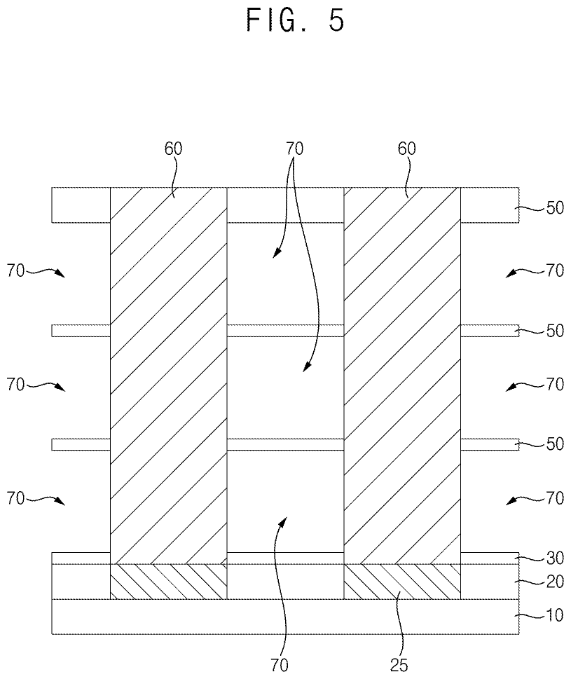

Referring to FIG. 5, the support layer 50 and the mold layer 40 may be partially removed to form a second opening exposing an upper surface of the first etch stop layer 30, and the mold layer 40 may be removed through the second opening. In example embodiments, the mold layer 40 may be removed by, e.g., a wet etching process, and a third opening 70 may be formed to expose a sidewall of each of the lower electrodes 60. However, the support layers 50 may remain on the sidewall of each of the lower electrodes 60. The upper surface of the first etch stop layer 30 and a surface of each of the support layers 50 may also be exposed by the third opening 70.

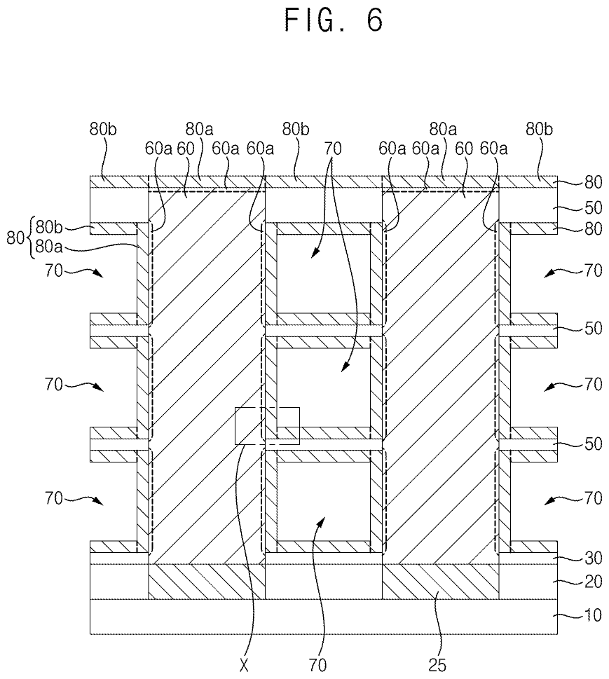

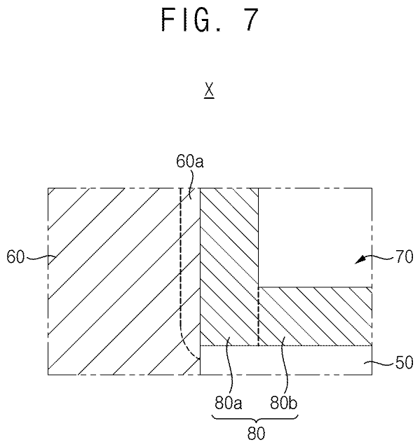

Referring to FIGS. 6 and 7, a first preliminary interface layer 80 may be formed on the sidewall of each of the lower electrodes 60, the upper surface of the first etch stop layer 30, and the surface of each of the support layers 50 exposed by the third opening 70. Hereinafter, a portion of the first preliminary interface layer 80 formed on an upper surface of the lower electrode 60 and the sidewall of the lower electrode 60 may be referred to as a first portion 80a, and a portion of the first preliminary interface layer 80 protruding in the horizontal direction from the first portion 80a and disposed (e.g., lengthwise) on the upper surface of the etch stop layer 30 and the surface of the support layer 50 may be referred to as a second portion 80b.

In example embodiments, the first preliminary interface layer 80 may be multi-layered, and accordingly, each layer of the first preliminary interface layer 80 may include a first metal, an oxide of the first metal or a nitride of the first metal. The layer containing the first metal may be formed by a deposition process using a source gas of the first metal, the layer containing an oxide of the first metal may be formed by a deposition process using a source gas of the first metal together with a source gas of oxygen, e.g., ozone plasma, and the layer containing a nitride of the first metal may be formed by a deposition process using a source gas of the first metal together with a source gas of nitrogen, e.g., ammonia. Each of the deposition process for forming the layers of the first preliminary interface layer 80 may be performed by, e.g., an atomic layer deposition (ALD) process. Accordingly, the layers may be formed conformally on the upper surface and the sidewall of the lower electrode 60 and the surface of the support layer 50.

In example embodiments, during the deposition processes, the first metal may penetrate into the first etch stop layer 30 and the support layers 50. Accordingly, each of the first etch stop layer 30 and the support layers 50 may further partially include the first metal.

A heat treatment process may be performed on the first preliminary interface layer 80 including the layers. The heat treatment process may be performed after all of the deposition processes for forming the plurality of layers, or may be performed between the deposition processes. For example, if the first preliminary interface layer 80 includes two layers, the heat treatment process may be performed after all of the deposition processes for forming the two layers of the first preliminary interface layer 80. On the other hand, if the first preliminary interface layer 80 includes three layers, the heat treatment process may be performed after two of the three layers are formed or after three of the three layers are formed.

By the heat treatment process, the first metal contained in the first portion 80a of the first preliminary interface layer 80 may diffuse to the lower electrode 60, and a portion of the lower electrode 60 to which the first metal is diffused may be referred to as the doped region 60a. The doped region 60a further containing the first metal may have increased conductivity compared to other portions of the lower electrode 60 that do not contain the first metal, and thus, conductivity of the lower electrode 60 may overall increase.

For example, a plurality of doped regions 60a of the lower electrode 60 may be spaced apart from each other in the vertical direction. In another example, if the heat treatment process is sufficiently performed, the first metal may further diffuse in the vertical direction, and thus, the doped regions 60a adjacent to each other in the vertical direction may merge with each other.

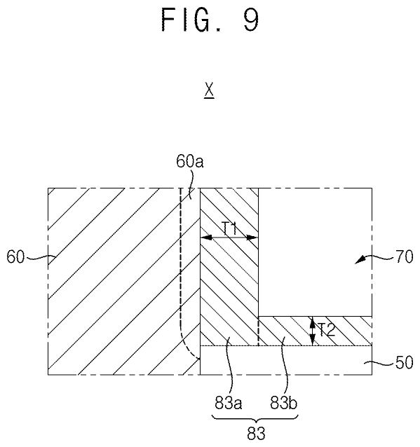

Referring to FIGS. 8 and 9, a selective etching process may be performed on the first

preliminary interface layer 80. Accordingly, the first preliminary interface layer 80 may be transformed into a first interface layer 83.

In detail, a composition of the first portion 80a of the first preliminary interface layer 80 and a composition the second portion 80b of the first preliminary interface layer 80 may differ from each other since diffusion of materials contained in each of the support layer 50, the lower electrode 60 or the first preliminary interface layer 80 may occur during the heat treatment process. Hence, the first portion 80a of the first preliminary interface layer 80 may have an etch selectivity with respect to the second portion 80b of the first preliminary interface layer 80.

Accordingly, the second portion 80b of the first preliminary interface layer 80 may be etched more than the first portion 80a of the first preliminary interface layer 80 by the selective etching process. By the selective etching process, the first preliminary interface layer 80 may be transformed into a first interface layer 83 including a third portion 83a on the upper surface and the sidewall of the lower electrode 60 and a fourth portion 83b on the upper surface of the first etch stop layer 30 and the surface of the support layer 50. The third portion 83a of the first interface layer 83 may have a first thickness T1 and the fourth portion 83b may have a second thickness T2 smaller than the first thickness T1. In example embodiments, the selective etching process may be performed by a wet etching process.

When the selective etching process is sufficiently performed, the second portion 80b of the first preliminary interface layer 80 remaining on the first etch stop layer 30 and the support layer 50 may be completely removed. Accordingly, leakage current through the second portion 80b of the first preliminary interface layer 80 may be prevented. However, if the first portion 80a of the first preliminary interface layer 80 is excessively etched, and the third portion 83a of the first interface layer 83 may not have a sufficient thickness, capacitance of the first capacitor 120 may be reduced. Accordingly, in example embodiments, the selective etching process may be performed so that the second portion 80b of the first preliminary interface layer 80 is not completely removed.

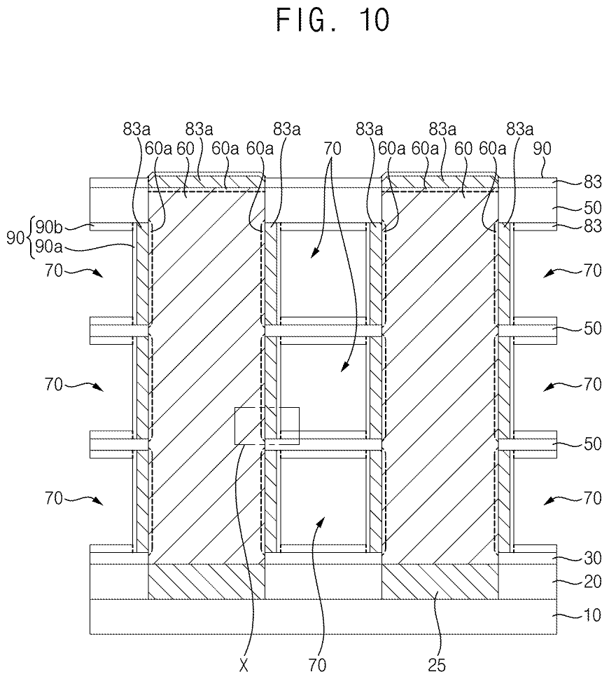

Referring to FIGS. 10 and 11, a second interface layer 90 may be formed on the first interface layer 83. In example embodiments, the second interface layer 90 may be formed by a deposition process using a source gas of the second metal together with a source gas of an oxide, e.g., ozone plasma. The deposition process may be performed by, e.g., an atomic layer deposition (ALD) process.

The second interface layer 90 formed on the third portion 83a of the first interface layer 83 by the deposition process (hereinafter, referred to as a fifth portion 90a) may have a third thickness T3. On the other hand, the second thickness T2 of the fourth portion 83b of the first interface layer 83 may be reduced by the selective etching process, and the fourth portion 83b of the first interface layer 83 may merge with the second interface layer 90. Accordingly, a portion of the first interface layer 83 formed on the upper surface of the first etch stop layer 30 and the surface the support layer 50 (hereinafter, referred to as a sixth portion 90b) may have a fourth thickness T4 that is greater than the third thickness T3.

The fourth portion 83b of the first interface layer 83 having conductivity, may merge with the second interface layer 90 and become electrically inactive. Thus, even if the second portion 80b of the first preliminary interface layer 80 is not completely removed, leakage current may be prevented.

Accordingly, the second portion 80b of the first preliminary interface layer 80 may not need to be completely removed by the selective etching process. Hence, thickness loss in the horizontal direction of the first portion 80a of the first preliminary interface layer 80 may not become excessively large. Accordingly, the first thickness T1 in the horizontal direction of the third portion 83a of the first interface layer 83 may be sufficiently large, and accordingly, the first capacitor 120 may have a large capacitance.

In example embodiments, the sixth portion 90b of the second interface layer 90 may be formed by merging with the fourth portion 83b of the first interface layer 83, and thus, the fourth thickness T4 of the sixth portion 90b of the second interface layer 90 may have a value similar to a sum of the first thickness T1 of the fourth portion 83b of the first interface layer 83 and the third thickness T3 that the second interface layer 90 may have if formed separately rather than merging with the first interface layer 83. (i.e., the fourth thickness T4≈the first thickness T1+third thickness T3).

In example embodiments, the deposition process may be performed by, e.g., an ALD process. During the deposition process, the second metal may penetrate into the first etch stop layer 30 and the support layer 50. Accordingly, each of the first etch stop layer 30 and the support layer 50 may further partially include the second metal.

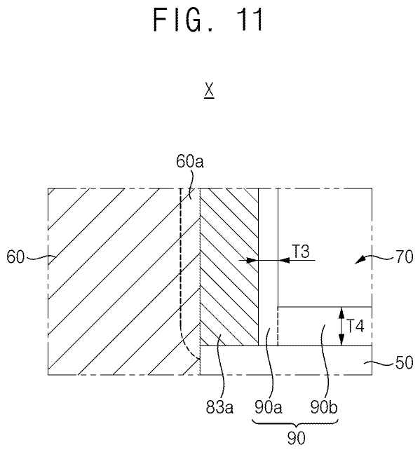

Referring to FIG. 12, a dielectric layer 100 may be formed on the second interface layer 90. In example embodiments, the dielectric layer 100 may be formed by a deposition process using a source gas of a metal, e.g., a hafnium source gas, a zirconium source gas, or an aluminum source gas, and an oxygen source, e.g., ozone plasma. Accordingly, the dielectric layer 100 may include a metal oxide, e.g., hafnium oxide, zirconium oxide, or aluminum oxide.

Referring to FIG. 1 again, an upper electrode layer may be formed on the dielectric layer 100. The dielectric layer 100 and the upper electrode layer may also be stacked on the upper surface of the lower electrode 60 and the upper surface of the uppermost one of the support layers 50.

Portions of the dielectric layer 100 and the upper electrode layer on the upper surface of the lower electrode 60 and the upper surface of the uppermost one of the support layers 50 may be removed.

Portions of the first and second interface layers 83 and 90, the dielectric layer 100 and the upper electrode layers remaining in the third opening 70 may be referred to as first and second interface patterns 85 and 95, a dielectric pattern 105 and an upper electrode 110, respectively. The first and second interface patterns 85 and 95 may collectively form an interface structure 97. The second interface pattern 95 may include the sixth portion 95b on the surface of the support layer 50 and the upper surface of the first etch stop layer 30, and the seventh portion 95a extending in the vertical direction to cover an outer sidewall of the first interface pattern 85.

The lower electrode 65, the interface structure 97 including the first and second interface patterns 85 and 95, the dielectric pattern 105 and the upper electrode 110 may collectively form the first capacitor 120.

The upper electrode plate 130 may be additionally formed on the first capacitor 120. The upper electrode plate 130 may include, e.g., doped silicon-germanium.

In the method of manufacturing the semiconductor device, the first preliminary interface layer 80 having conductivity may be formed on the sidewall of the lower electrode 60, the upper surface of the first etch stop layer 30, and the surface of each of the support layers 50, and the first portion 80a of the first preliminary interface layer 80 on the upper surface of the first etch stop layer 30 and the surface of each of the support layers 50 may be removed by the selective etching so as to transform the first preliminary interface layer 80 into the first interface layer 83.

If the fourth portion 83b of the first interface layer 83 remaining on the upper surface of the first etch stop layer 30 and the surface of each of the support layers 50 is not sufficiently removed, leakage current may occur. On the other hand, if the selective etching process is excessively performed to completely remove the fourth portion 83b of the first interface layer 83, thickness of the third portion 83a of the first interface layer 83 on the sidewall of the lower electrode 60 may also be reduced, and thus, sufficient capacitance may not be secured.

However, in the method of manufacturing the first capacitor 120, the second interface layer 90 may be additionally formed on the first interface layer 83. Accordingly, the fourth portion 83b of the first interface layer 83, which has conductivity and remains on the upper surface of the first etch stop layer 30 and the surface of each of the support layer 50, may merge with the second interface layer 90 to become non-conductive, and thus, leakage current may be prevented even if the fourth portion 83b of the first interface layer 83 is not completely removed during the selective etching process.

In addition, the selective etching process may prevent the third portion 83a of the first interface layer 83 formed on the sidewall of the lower electrode 60 from being excessively etched, and thus, the first capacitor 120 may have sufficient capacitance.

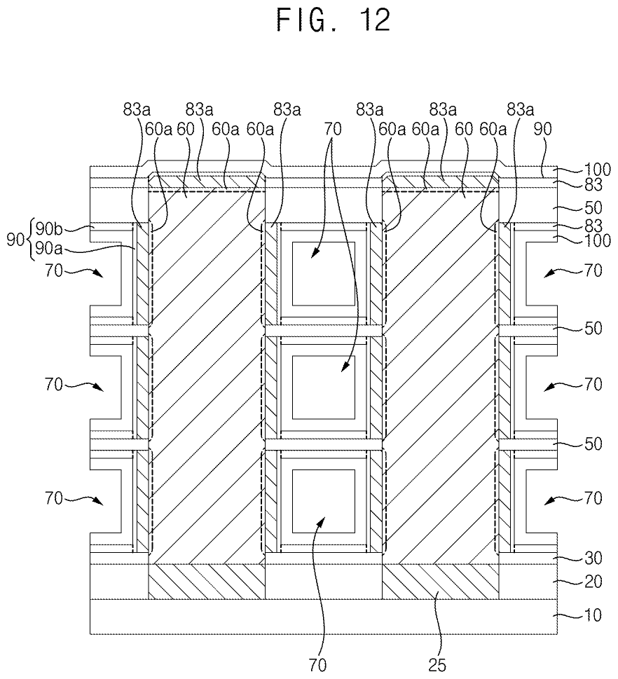

FIG. 13 is a cross-sectional view illustrating a second capacitor structure in accordance

with example embodiments. The second capacitor structure may be substantially the same as or similar to the first capacitor structure, except for further including an interface oxide layer 107. Thus, repeated explanations are omitted herein.

Referring to FIG. 13, the second capacitor structure may include a second capacitor 120′, and the second capacitor 120′ may further include the interface oxide layer 107 disposed between the dielectric pattern 105 and the upper electrode 110. Accordingly, the interface oxide layer 107 may contact an upper surface of the dielectric pattern 105 instead of the upper electrode 110.

The interface oxide layer 107 may include an oxide of a metal, e.g., scandium (Sc), yttrium (Y), titanium (Ti), vanadium (V), niobium (Nb), tantalum (Ta), chromium (Cr), Molybdenum (Mo), tungsten (W), iron (Fe), ruthenium (Ru), osmium (Os), cobalt (Co), rhodium (Rh), iridium (Ir), boron (B), tin (Sn), etc. The interface oxide layer 107 may be formed on the dielectric layer 100 by a deposition process, e.g., an atomic layer deposition (ALD) process, a chemical vapor deposition (CVD) process, etc.

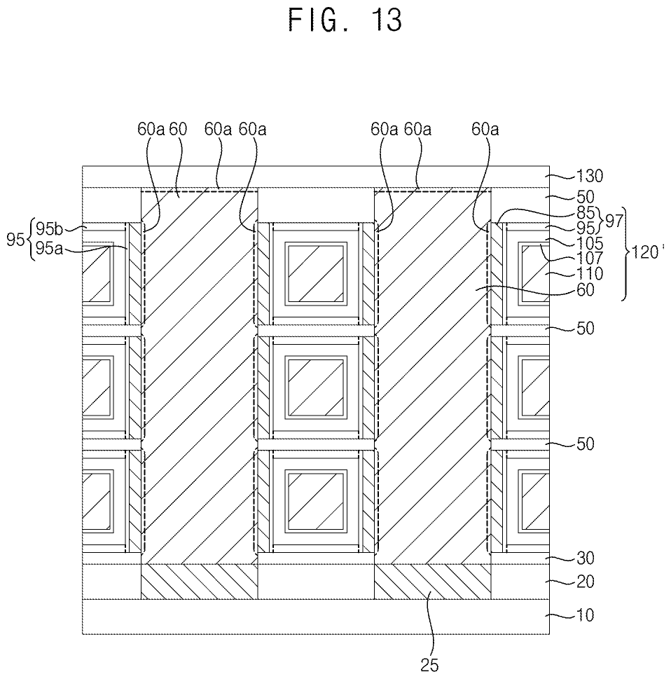

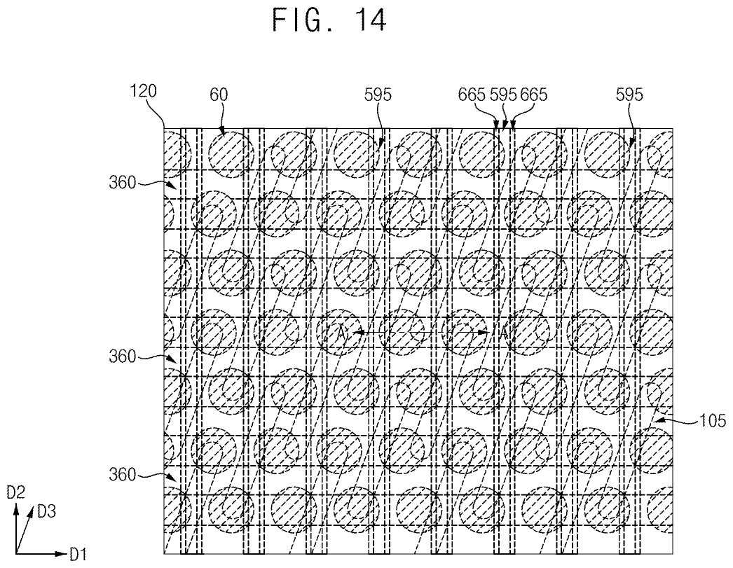

FIG. 14 is a plan view illustrating a semiconductor device in accordance with example embodiments, and FIG. 15 is a cross-sectional view taken along line A-A′ of FIG. 14.

This semiconductor device of FIGS. 14-15 may be an application of the first capacitor structure illustrated with reference to FIG. 1 to a DRAM device, and thus repeated explanations of the first capacitor structure are omitted herein. However, the semiconductor device may include one of the second capacitor structure shown in FIG. 13 instead of the first capacitor structure.

Hereinafter, two directions among horizontal directions that are substantially parallel to an upper surface of a substrate 300, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of the substrate 300 may be referred to as a vertical direction.

Referring to FIGS. 14 and 15, the semiconductor device may include an active pattern 305, a gate structure 360, a first bit line structure 595, a contact plug structure, and the first capacitor structure on the substrate 300. The semiconductor device may further include an isolation pattern 310, a spacer structure 665, a fourth spacer 690, a second capping pattern 685, first and second insulation pattern structures 435 and 790, fifth and sixth insulation patterns 610 and 620, and a metal silicide pattern 700.

The active pattern 305 may extend (e.g., lengthwise) in the third direction D3, and a plurality of active patterns 305 may be spaced apart from each other in the first and second directions D1 and D2. A sidewall of the active pattern 305 may be covered by the isolation pattern 310. The active pattern 305 may include substantially the same material as the substrate 300, and the isolation pattern 310 may include an oxide, e.g., silicon oxide.

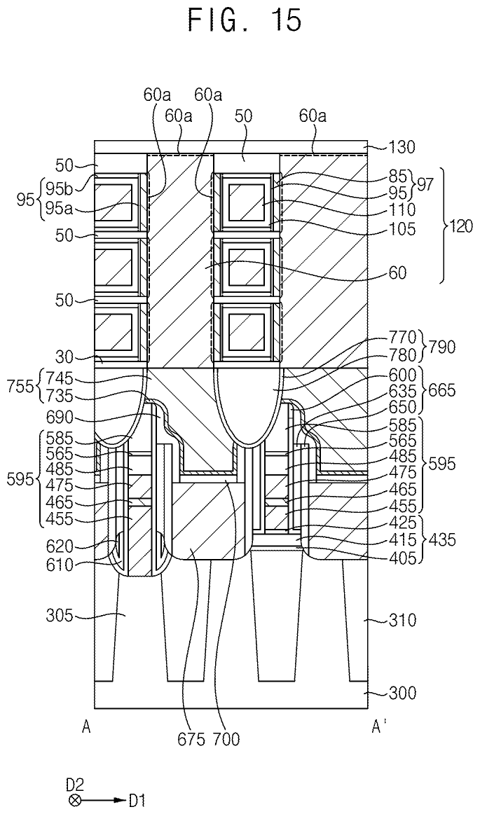

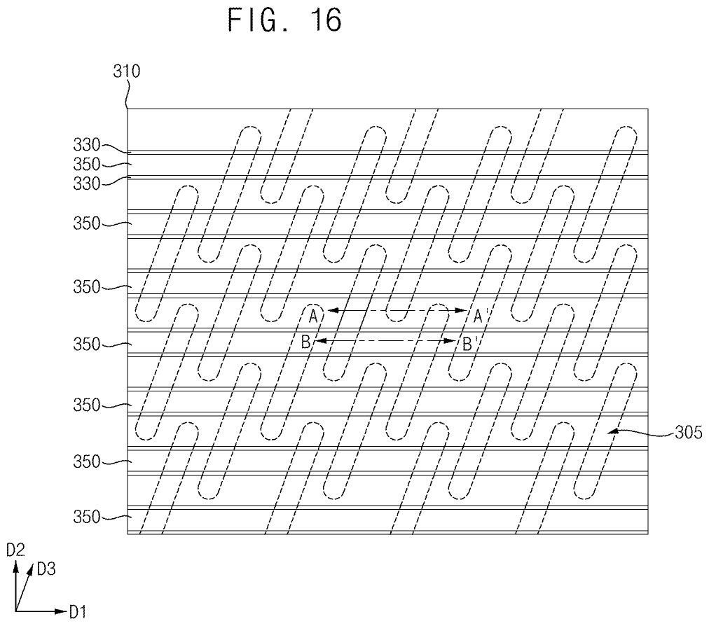

Referring to FIGS. 14 and 15 together with FIGS. 16 and 17, the gate structure 360 may be formed in a second recess extending (e.g., lengthwise) in the first direction D1 through upper portions of the active pattern 305 and the isolation pattern 310. The gate structure 360 may include a first gate insulation pattern 330 on a bottom and a sidewall of the second recess, a first gate electrode 340 on a portion of the first gate insulation pattern 330 on the bottom and a lower sidewall of the second recess, and a gate mask 350 on the first gate electrode 340 and filling an upper portion of the second recess.

The first gate insulation pattern 330 may include an oxide, e.g., silicon oxide, the first gate electrode 340 may include, e.g., at least one of a metal, a metal nitride, a metal silicide, etc., and the gate mask 350 may include an insulating nitride, e.g., silicon nitride. In example embodiments, the gate structure 360 may extend in the first direction D1, and a plurality of gate structures 360 may be spaced apart from each other in the second direction D2.

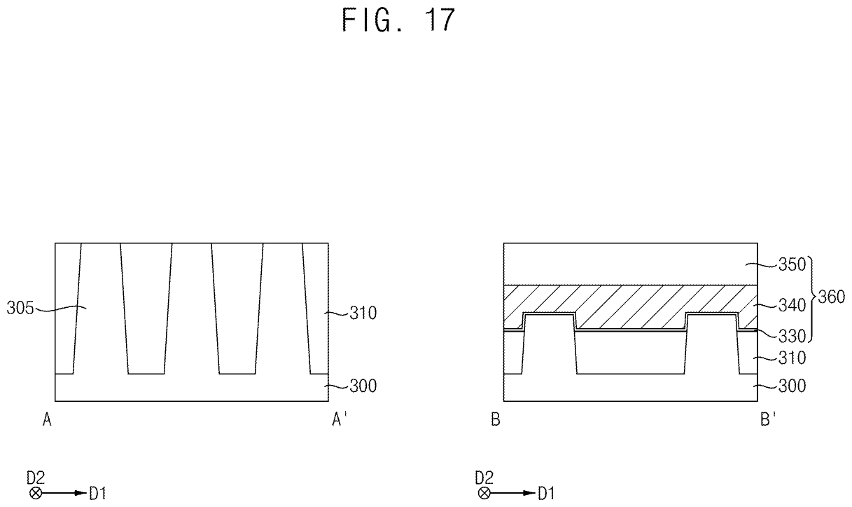

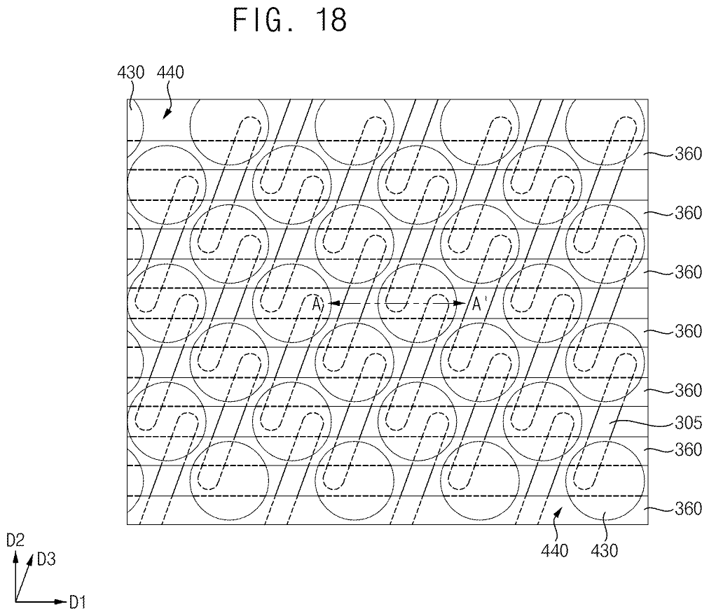

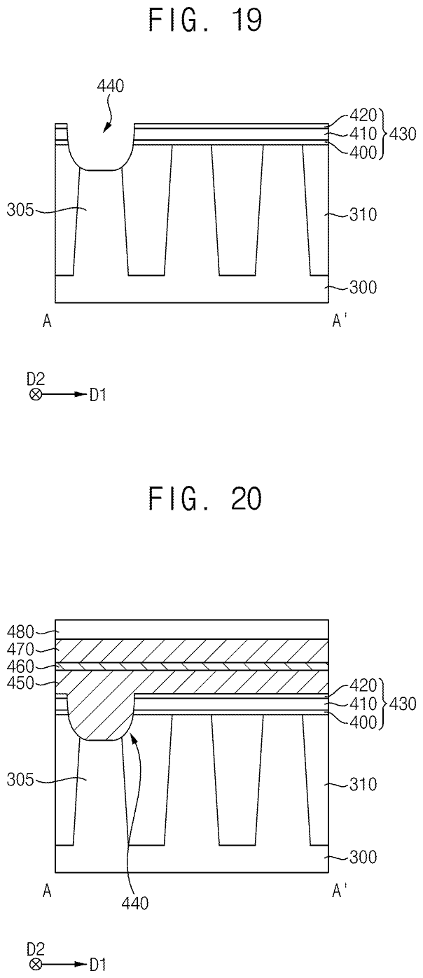

Referring to FIGS. 14 and 15 together with FIGS. 18 and 19, a fourth opening 440 extending through an insulating layer structure 430 and exposing upper surfaces of the active pattern 305, the isolation pattern 310 and the gate mask 350 of the gate structure 360 may be formed, and an upper surface of a central portion in the third direction D3 of the active pattern 305 may be exposed by the fourth opening 440.

In example embodiments, an area of a bottom of the fourth opening 440 may be greater than an area of the upper surface of the active pattern 305. Thus, the fourth opening 440 may also expose an upper surface of a portion of the isolation pattern 310 adjacent to the active pattern 305. Additionally, the fourth opening 440 may extend through upper portions of the active pattern 305 and the portion of the isolation pattern 310 adjacent thereto, and thus the bottom of the fourth opening 440 may be lower than an upper surface of each of opposite ends (e.g., edge portions) in the third direction D3 of the active pattern 305.

The first bit line structure 595 may include a second conductive pattern 455, a first barrier pattern 465, a third conductive pattern 475, a first mask 485, a second etch stop pattern 565 and a first capping pattern 585 sequentially stacked in the vertical direction on the fourth opening 440 or the first insulation pattern structure 435 (FIG. 23). The second conductive pattern 455, the first barrier pattern 465 and the third conductive pattern 475 may collectively form a conductive structure, and the first mask 485, the second etch stop pattern 565 and the first capping pattern 585 may collectively form an insulation structure.

The second conductive pattern 455 may include, e.g., doped polysilicon, the first barrier pattern 465 may include a metal nitride, e.g., titanium nitride, or a metal silicon nitride, e.g., titanium silicon nitride, the third conductive pattern 475 may include a metal, e.g., tungsten, and each of the first mask 485, the second etch stop pattern 565 and the first capping pattern 585 may include an insulating nitride, e.g., silicon nitride. In example embodiments, the first bit line structure 595 may extend (e.g., lengthwise) in the second direction D2 on the substrate 300, and a plurality of first bit line structures 595 may be spaced apart from each other in the first direction D1.

The fifth and sixth insulation patterns 610 and 620 may be formed in the fourth opening 440, and may contact a lower sidewall of the first bit line structure 595. The fifth insulation pattern 610 may include an oxide, e.g., silicon oxide, and the sixth insulation pattern 620 may include an insulating nitride, e.g., silicon nitride.

The first insulation pattern structure 435 may be formed on the active pattern 305 and the isolation pattern 310 under the first bit line structure 595, and may include second, third and fourth insulation patterns 405, 415 and 425 sequentially stacked in the vertical direction. The second and fourth insulation patterns 405 and 425 may include an oxide, e.g., silicon oxide, and the third insulation pattern 415 may include an insulating nitride, e.g., silicon nitride.

The contact plug structure may include a lower contact plug 675, a metal silicide pattern 700 and an upper contact plug 755 sequentially stacked in the vertical direction on the active pattern 305 and the isolation pattern 310.

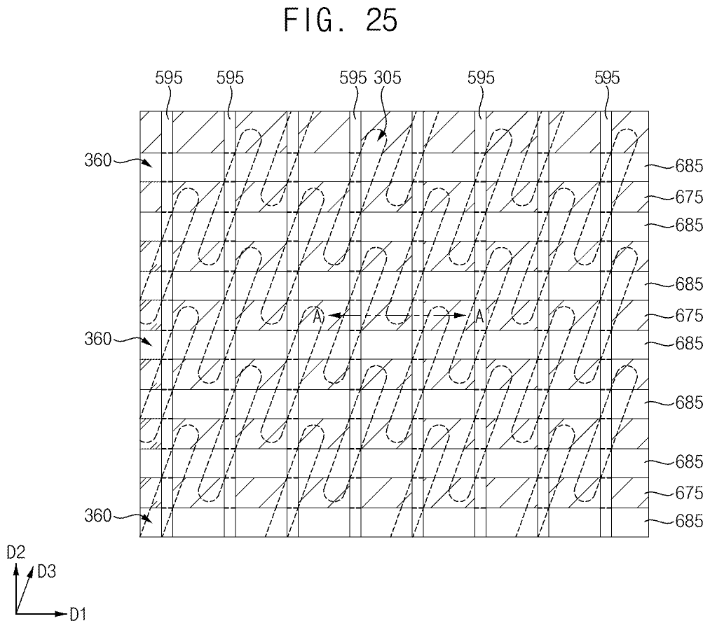

The lower contact plug 675 may contact the upper surface of each of opposite edge portions in the third direction D3 of the active pattern 305. In example embodiments, a plurality of lower contact plugs 675 may be spaced apart from each other in the second direction D2, and the second capping pattern 685 may be formed between neighboring ones of the lower contact plugs 675 in the second direction D2 (FIG. 25). The second capping pattern 685 may include an insulating nitride, e.g., silicon nitride. The lower contact plug 675 may include, e.g., doped polysilicon, the metal silicide pattern 700 may include, e.g., titanium silicide, cobalt silicide, nickel silicide, etc.

The upper contact plug 755 may include a second metal pattern 745 and a second barrier pattern 735 covering a lower surface of the second metal pattern 745. The second metal pattern 745 may include a metal, e.g., tungsten, and the second barrier pattern 735 may include a metal nitride, e.g., titanium nitride.

In example embodiments, a plurality of upper contact plugs 755 may be spaced apart from each other in the first and second directions D1 and D2, and may be arranged in a honeycomb pattern or a lattice pattern in a plan view. Each of the upper contact plugs 755 may have a shape of, e.g., a circle, an ellipse, or a polygon in a plan view.

The spacer structure 665 may include a first spacer 600 covering sidewalls of the first bit line structure 595 and the fourth insulation pattern 425, an air spacer 635 on a lower outer sidewall of the first spacer 600, and a third spacer 650 on an outer sidewall of the air spacer 635, a sidewall of the first insulation pattern structure 435, and upper surfaces of the fifth and sixth insulation patterns 610 and 620. Each of the first and third spacers 600 and 650 may include an insulating nitride, e.g., silicon nitride, and the air spacer 895 may include air.

The fourth spacer 690 may be formed on an outer sidewall of a portion of the first spacer 600 on an upper sidewall of the first bit line structure 595, and may cover an upper end of the air spacer 635 and an upper surface of the third spacer 650. The fourth spacer 690 may include an insulating nitride, e.g., silicon nitride.

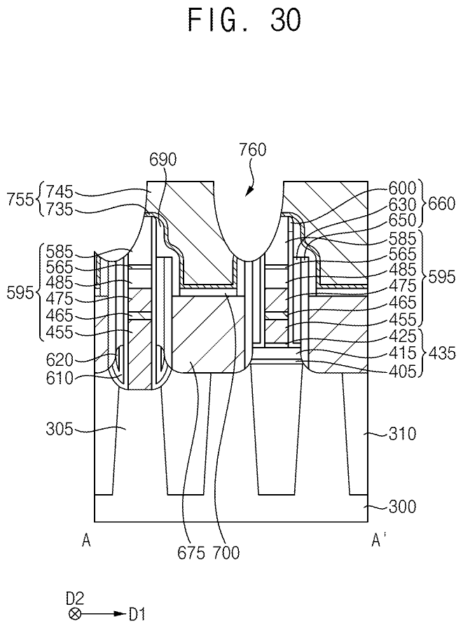

Referring to FIGS. 14 and 15 together with FIGS. 29 and 30, the second insulation pattern structure 790 may include a seventh insulation pattern 770 on an inner wall of a ninth opening 760, which may extend through the upper contact plug 755, a portion of the insulation structure of the first bit line structure 595 and portions of the first, third and fourth spacers 600, 650 and 690 and surround the upper contact plug 755 in a plan view, and an eighth insulation pattern 780 on the seventh insulation pattern 770 and fill a remaining portion of the ninth opening 760. The upper end of the air spacer 635 may be closed by the seventh insulation pattern 770. The seventh and eighth insulation patterns 770 and 780 may include an insulating nitride, e.g., silicon nitride.

The first etch stop layer 30 may be formed on the seventh and eighth insulation patterns 770 and 780, the upper contact plug 755 and the second capping pattern 685. The first capacitor 120 may contact an upper surface of the upper contact plug 755.

FIGS. 14 to 31 are plan views and cross-sectional views illustrating a method of

manufacturing a semiconductor device according to example embodiments. Specifically, FIGS. 14, 16, 18, 21, 25 and 29 are the plan views, FIG. 17 includes cross-sectional views taken along lines A-A′ and B-B′ of FIG. 16, and FIGS. 19-20, 22-24, 26-28 and 30-31are cross-sectional views taken along line A-A′ of corresponding plan views.

The method of manufacturing the semiconductor device is an application of the method of forming the first capacitor structure described with reference to FIGS. 1 to 12 to a method of manufacturing a DRAM device, and repeated explanations of the method of forming the capacitor structure are omitted herein.

Referring to FIGS. 16 and 17, an upper portion of the substrate 300 may be removed to form a first recess, and the isolation pattern 310 may be formed in the first recess. As the isolation pattern 310 is formed on the substrate 300, the active pattern 305 of which a sidewall is covered by the isolation pattern 310 may be defined.

The active pattern 305 and the isolation pattern 310 on the substrate 300 may be partially etched to form a second recess extending in the first direction D1, and the gate structure 360 may be formed in the second recess. In example embodiments, the gate structure 360 may extend in the first direction D1, and a plurality of gate structures may be spaced apart from each other in the second direction D2.

Referring to FIGS. 18 and 19, the insulating layer structure 430 may be formed on the active pattern 305, the isolation pattern 310, and the gate structure 360. The insulating layer structure 430 may include the second to fourth insulating layers 400, 410, and 420 sequentially stacked.

The insulating layer structure 430 may be patterned, and the active pattern 305, the isolation pattern 310, and the gate mask 350 included in the gate structure 360 may be partially etched using the patterned insulating layer structure 430 as an etching mask to form a fourth opening 440. In example embodiments, the insulating layer structure 430 may have a circular shape or an elliptical shape in a plain view, and a plurality of insulating layer structures 430 may be spaced apart from each other in the first and second direction D1 and D2. Each of the insulating layer structures 430 may overlap end portions of ones of the active patterns 305 neighboring in the third direction D3, which may face each other, in a vertical direction substantially orthogonal to the upper surface of the substrate 300.

Referring to FIG. 20, a first conductive layer 450, a first barrier layer 460, a second conductive layer 470 and a first mask layer 480 may be sequentially stacked on the insulating layer structure 430, and the active pattern 305, the isolation pattern 310 and the gate structure 360 exposed by the fourth opening 440. The first conductive layer 450 may fill the fourth opening 440.

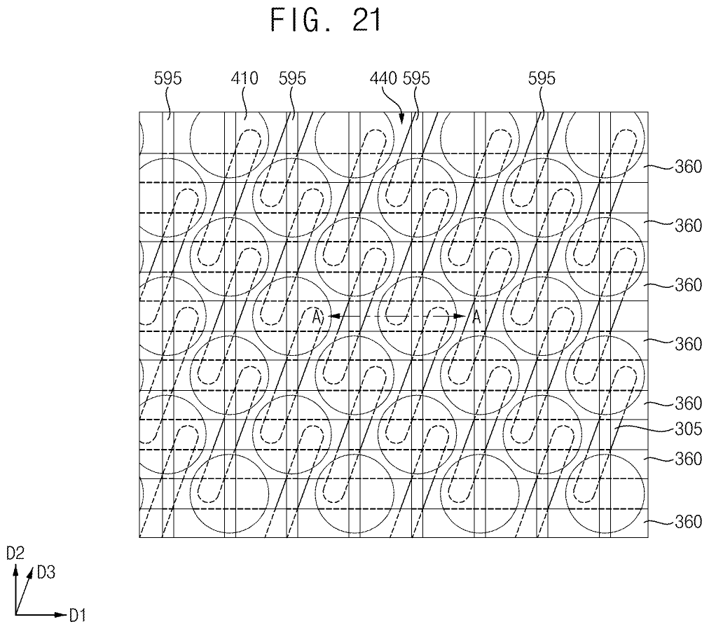

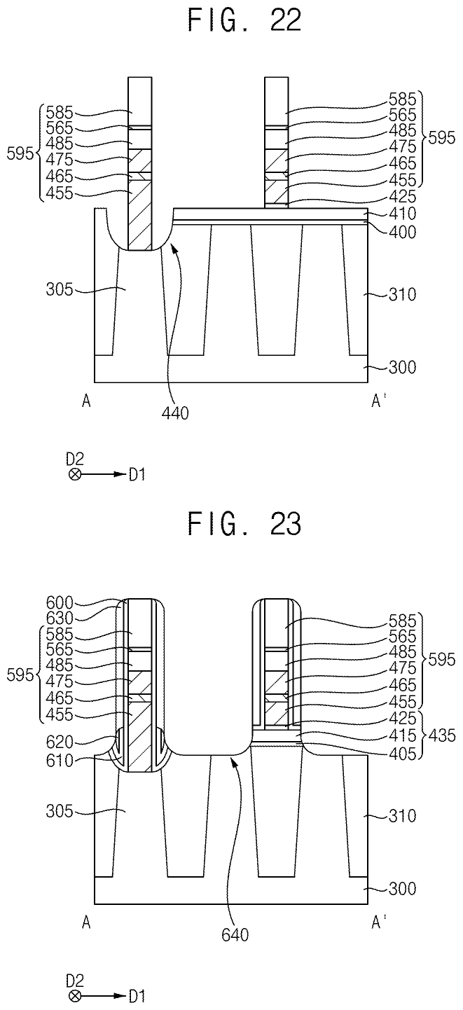

Referring to FIGS. 21 and 22, a second etch stop layer and a first capping layer may be sequentially formed on the conductive structure layer, the first capping layer may be etched to form a first capping pattern 585, and the second etch stop layer, the first mask layer 480, the second conductive layer 470, the first barrier layer 460 and the first conductive layer 450 may be sequentially etched using the first capping pattern 585 as an etch mask.

In example embodiments, the first capping pattern 585 may extend in the second direction D2, and a plurality of first capping patterns 585 may be spaced apart from each other in the first direction D1.

By the etching process, a second conductive pattern 455, a first barrier pattern 465, a third conductive pattern 475, a first mask 485, a second etch stop pattern 565 and the first capping pattern 585 may be formed on the fourth opening 440, and a fourth insulation pattern 425, the second conductive pattern 455, the first barrier pattern 465, the third conductive pattern 475, the first mask 485, the second etch stop pattern 565 and the first capping pattern 585 may be sequentially stacked on the third insulating layer 410 of the insulating layer structure 430 at an outside of the fourth opening 440.

Hereinafter, the second conductive pattern 455, the first barrier pattern 465, the third conductive pattern 475, the first mask 485, the second etch stop pattern 565 and the first capping pattern 585 sequentially stacked may be referred to as a first bit line structure 595. The second conductive pattern 455, the first barrier pattern 465 and the third conductive pattern 475 may form a conductive structure, and the first mask 485, the second etch stop pattern 565 and the first capping pattern 585 may form an insulating structure. In example embodiments, the first bit line structure 595 may extend in the second direction D2, and a plurality of first bit line structures 595 may be spaced apart from each other in the first direction D1.

Referring to FIG. 23, a first spacer layer may be formed on the substrate 300 on which the first bit line structure 595 is formed, and fifth and sixth insulating layers may be sequentially formed on the first spacer layer.

The first spacer layer may also cover a sidewall of the fourth insulation pattern 425 under the first bit line structure 595 on the third insulating layer 410, and the sixth insulating layer may fill a remaining portion of the fourth opening 440.

The fifth and sixth insulating layers may be etched by an etching process. In example embodiments, the etching process may be a wet etching process using, e.g., phosphoric acid (H₂PO₃), SC1, and hydrofluoric acid (HF) as an etchant, and portions of the fifth and sixth insulating layers except for portions thereof in the fourth opening 440 may be removed. Accordingly, most portion of a surface of the first spacer layer, that is, all portions of the surface of the first spacer layer except for a portion of the surface thereof in the fourth opening 440 may be exposed, and the fifth and sixth insulating layers remaining in the fourth opening 440 may form fifth and sixth insulation patterns 610 and 620, respectively.

A second spacer layer may be formed on the exposed surface of the first spacer layer and the fifth and sixth insulation patterns 610 and 620 in the fourth opening 440. The second spacer layer may be anisotropically etched to form a second spacer 630 covering a sidewall of the first bit line structure 595 on the surface of the first spacer layer and on the fifth and sixth insulation patterns 610 and 620.

A dry etching process may be performed using the first capping pattern 585 and the second spacer 630 as an etch mask to form a fifth opening 640 exposing an upper surface of the active pattern 305, and upper surfaces of the isolation pattern 310 the gate mask 350 may also be exposed by the fifth opening 640.

By the dry etching process, portions of the first spacer layer on upper surfaces of the first capping pattern 585 and the third insulating layer 410 may be removed, and thus a first spacer 600 may be formed on the sidewall of the first bit line structure 595. By the dry etching process, the second and third insulating layers 400 and 410 may be partially removed to remain as second and third insulation patterns 405 and 415, respectively, under the first bit line structure 595. The second to fourth insulation patterns 405, 415 and 425 sequentially stacked under the first bit line structure 595 may form a first insulation pattern structure.

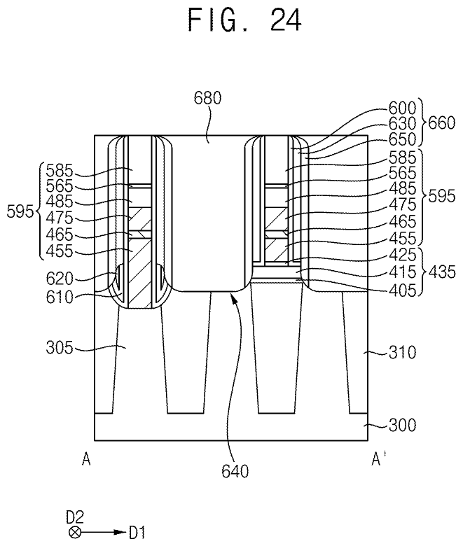

Referring to FIG. 24, a third spacer layer may be formed on an upper surface of the first capping pattern 585, an outer sidewall of the second spacer 630, portions of the upper surfaces of the fifth and sixth insulation patterns 610 and 620, and upper surfaces of the active pattern 305, the isolation pattern 310 and the gate mask 350 exposed by the fifth opening 640. The third spacer layer may be anisotropically etched to form a third spacer 650 covering the sidewall of the first bit line structure 595.

The first to third spacers 600, 630 and 650 sequentially stacked on the sidewall of the first bit line structure 595 in the horizontal direction may be referred to as a preliminary spacer structure 660.

A second sacrificial layer may be formed to fill the fifth opening 640 on the substrate 300 to a sufficient height, and an upper portion of the second sacrificial layer may be planarized until the upper surface of the first capping pattern 585 is exposed to form a second sacrificial pattern 680 in the fifth opening 640.

In example embodiments, the second sacrificial pattern 680 may extend in the second direction D2, and a plurality of second sacrificial patterns 680 may be spaced apart from each other in the first direction D1 by the first bit line structures 595. For example, the second sacrificial pattern 680 may include an oxide, e.g., silicon oxide.

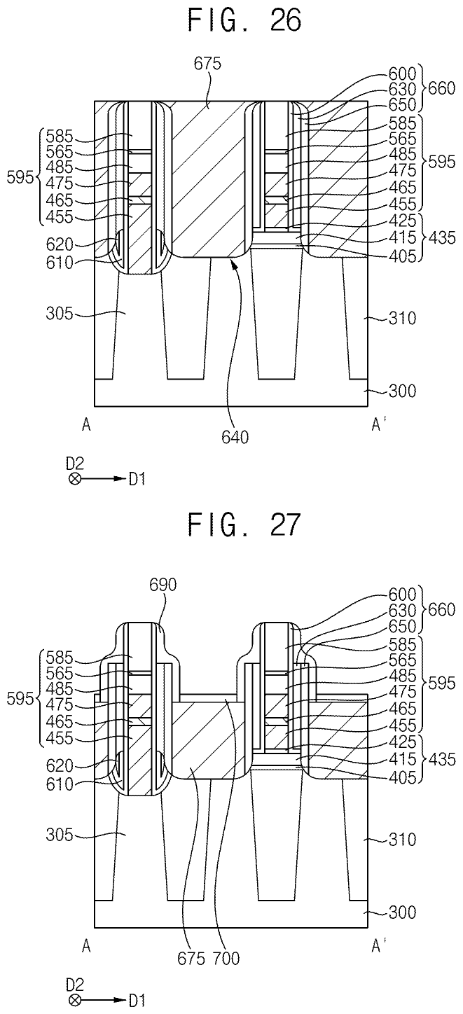

Referring to FIGS. 25 and 26, a second mask including a plurality of sixth openings, each of which may extend in the first direction D1, spaced apart from each other in the second direction D2 may be formed on the first capping pattern 585, the second sacrificial pattern 680 and the preliminary spacer structure 660, and may be etched using the second mask as an etching mask.

In example embodiments, each of the sixth openings may overlap a region between the gate structures 360 in the vertical direction. By the etching process, a seventh opening exposing upper surfaces of the active pattern 305 and the isolation pattern 310 may be formed between the first bit line structures 595 on the substrate 300.

The second mask may be removed, a lower contact plug layer may be formed to fill the seventh opening to a sufficient height, and an upper portion of the lower contact plug layer may be planarized until the upper surface of the first capping pattern 585 and upper surfaces of the second sacrificial pattern 680 and the preliminary spacer structure 660 are exposed. Thus, the lower contact plug layer may be transformed into a plurality of lower contact plugs 675 spaced apart from each other in the second direction D2 between the first bit line structures 595. Additionally, the second sacrificial pattern 680 extending in the second direction D2 between the first bit line structures 595 may be divided into a plurality of parts in the second direction D2 by the lower contact plugs 675.

The second sacrificial pattern 680 may be removed to form an eighth opening, and a second capping pattern 685 may be formed to fill the eighth opening. In example embodiments, the second capping pattern 685 may overlap the gate structure 360 in the vertical direction.

Referring to FIG. 27, an upper portion of the lower contact plug 675 may be removed to expose an upper portion of the preliminary spacer structure 660 on the sidewall of the first bit line structure 595, and upper portions of the second and third spacers 630 and 650 of the exposed preliminary spacer structure 660 may be removed.

An upper portion of the lower contact plug 675 may be additionally removed. Thus, an upper surface of the lower contact plug 675 may be lower than upper surfaces of the second and third spacers 630 and 650.

A fourth spacer layer may be formed on the first bit line structure 595, the preliminary spacer structure 660, the second capping pattern 685 and the lower contact plug 675, and may be anisotropically etched to form a fourth spacer 690 covering an upper portion of the preliminary spacer structure 660 on the sidewall of the first bit line structure 595, and the upper surface of the lower contact plug 675 may be exposed by the etching process.

A metal silicide pattern 700 may be formed on the exposed upper surface of the lower contact plug 675. In example embodiments, the metal silicide pattern 700 may be formed by forming a first metal layer on the first and second capping patterns 585 and 685, the fourth spacer 690 and the lower contact plug 675, performing a heat treatment thereon, and removing an unreacted portion of the first metal layer.

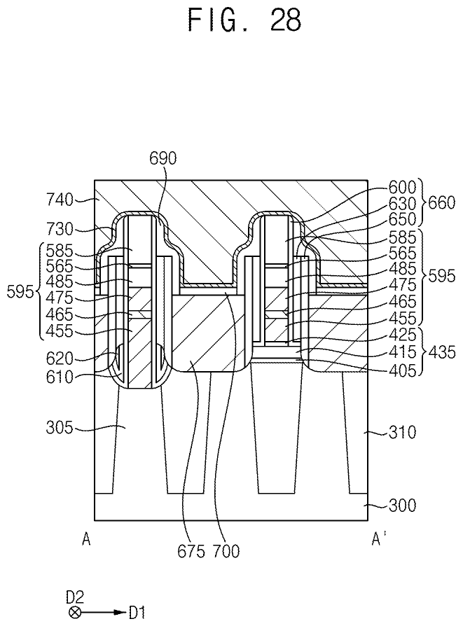

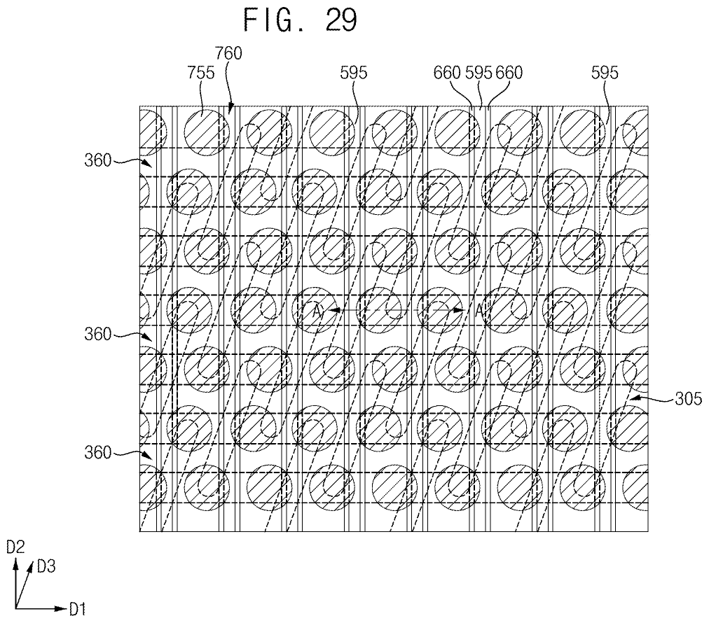

Referring to FIG. 28, a second barrier layer 730 may be formed on the first and second capping patterns 585 and 685, the fourth spacer 690, the metal silicide pattern 700 and the lower contact plug 675, and a second metal layer 740 may be formed on the second barrier layer 730 to fill a space between the first bit line structures 595.

A planarization process may be performed on an upper portion of the second metal layer 740. The planarization process may include, e.g., a chemical mechanical polishing (CMP) process and/or an etch-back process.

Referring to FIGS. 29 and 30, the second metal layer 740 and the second barrier layer 730 may be patterned to form an upper contact plug 755. In example embodiments, a plurality of upper contact plugs 755 may be formed, and a ninth opening 760 may be formed between the upper contact plugs 755.

The ninth opening 760 may be formed by partially removing the first and second capping patterns 585 and 685, the preliminary spacer structure 660 and the fourth spacer 690 as well as the second metal layer 740 and the second barrier layer 730.

The upper contact plug 755 may include a second metal pattern 745 and a second barrier pattern 735 covering a lower surface of the second metal pattern 745. In example embodiments, the upper contact plug 755 may have a shape of a circle, an ellipse, or a rounded polygon in a plan view, and the upper contact plugs 755 may be arranged, e.g., in a honeycomb pattern in the first and second direction D1 and D2, in a plan view.

The lower contact plug 675, the metal silicide pattern 700 and the upper contact plug 755 sequentially stacked on the substrate 300 may collectively form a contact plug structure.

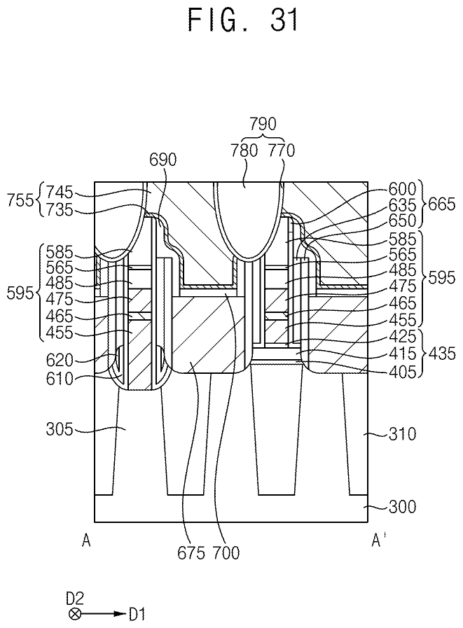

Referring to FIG. 31, the second spacer 630 included in the preliminary spacer structure 660 exposed by the ninth opening 760 may be removed to form an air gap, a seventh insulation pattern 770 may be formed on a bottom and a sidewall of the ninth opening 760, and an eighth insulation pattern 780 may be formed to fill a remaining portion of the ninth opening 760. Each of the seventh and eighth insulation patterns 770 and 780 may form a second insulation pattern structure 790.

A top end of the air gap may be covered by the seventh insulation pattern 770, and thus an air spacer 635 may be formed. The first spacer 600, the air spacer 635 and the third spacer 650 may form a spacer structure 665.

Referring to FIGS. 14 and 15 again, the first capacitor 120, the first etch stop layer 30, the support layer 50 and the upper electrode plate 130 may be formed by processes substantially the same as or similar to the processes described with reference to FIGS. 1 to 12. The lower electrode 60 included in the first capacitor 120 may contact an upper surface of the upper contact plug 755.

By way of summation and review, an interface layer between the lower electrode and the dielectric layer may increase capacitance of a capacitor structure, as the integration degree of the DRAM device increases. However, if the interface layer remains on surfaces of the support layers, leakage current may increase.

In contrast, example embodiments provide a capacitor structure having improved characteristics. Example embodiments also provide a semiconductor device including the capacitor structure having improved characteristics.

That is, a capacitor structure in accordance with example embodiments may include an interface structure disposed between a lower electrode and a dielectric layer, and thus capacitance of the capacitor structure may increase. The interface structure may include a first interface pattern on a sidewall of the lower electrode and a second interface pattern on a surface of a support layer between the lower electrodes. The second interface pattern may have insulating properties, and hence, leakage current may decrease.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A capacitor structure, comprising:
a lower electrode on a substrate;
a support layer on a sidewall of the lower electrode, the support layer including an insulating material;
an interface structure on the lower electrode, the interface structure including:
a first interface pattern on the sidewall of the lower electrode, the first interface pattern including a first metal, and
a second interface pattern on the first interface pattern and including an oxide of a second metal, the second interface pattern including a first portion on an outer sidewall of the first interface pattern and a second portion extending from the first portion along a surface of the support layer, and the second portion including the first metal;
a dielectric pattern on the interface structure; and
an upper electrode on the dielectric pattern.

2. The capacitor structure of claim 1, wherein a thickness in a vertical direction of the second portion of the second interface pattern is greater than a thickness in a horizontal direction of the first portion of the second interface pattern, the vertical direction being substantially perpendicular to an upper surface of the substrate, and the horizontal direction being substantially parallel to the upper surface of the substrate.

3. The capacitor structure of claim 1, wherein the first interface pattern includes the first metal, an oxide of the first metal or a nitride of the first metal.

4. The capacitor structure of claim 1, wherein the first metal includes scandium (Sc), yttrium (Y), titanium (Ti), vanadium (V), niobium (Nb), tantalum (Ta), chromium (Cr), molybdenum (Mo), tungsten (W), iron (Fe), ruthenium (Ru), osmium (Os), cobalt (Co), rhodium (Rh), iridium (Ir), boron (B) or tin (Sn).

5. The capacitor structure of claim 1, wherein the second metal includes a metal with four valance electrons or a metal with three valance electrons.

6. The capacitor structure of claim 1, wherein a thickness of the second portion of the second interface pattern is in a range of about 0.5 angstroms to about 2 angstroms.

7. The capacitor structure of claim 1, wherein the support layer further includes the first metal and the second metal.

8. The capacitor structure of claim 1, wherein a portion of the lower electrode contacting the first interface pattern further includes the first metal.

9. A capacitor structure, comprising:
a lower electrode on a substrate;
a support layer on a sidewall of the lower electrode, the support layer including an insulating material;
an interface structure on the lower electrode, the interface structure including:
a first interface pattern on the sidewall of the lower electrode, the first interface pattern including an oxide of a first metal, and
a second interface pattern on the first interface pattern and including an oxide of a second metal, the second interface pattern including a first portion on an outer sidewall of the first interface pattern and a second portion extending from the first portion along a surface of the support layer;
a dielectric pattern on the interface structure; and
an upper electrode on the dielectric pattern,
wherein a thickness a vertical direction of the second portion of the second interface pattern is greater than a thickness in a horizontal direction of the first portion of the second interface pattern, the vertical direction being substantially perpendicular to an upper surface of the substrate, and the horizontal direction being substantially parallel to the upper surface of the substrate.

10. The capacitor structure of claim 9, wherein the second portion of the second interface pattern further includes the first metal.

11. The capacitor structure of claim 9, wherein the first metal includes scandium (Sc), yttrium (Y), titanium (Ti), vanadium (V), niobium (Nb), tantalum (Ta), chromium (Cr), molybdenum (Mo), tungsten (W), iron (Fe), ruthenium (Ru), osmium (Os), cobalt (Co), rhodium (Rh), iridium (Ir), boron (B) or tin (Sn).

12. The capacitor structure of claim 9, wherein the second metal includes a metal with four valance electrons or a metal with three valance electrons.

13. The capacitor structure of claim 9, wherein a thickness of the second portion of the second interface pattern is in a range of about 0.5 angstroms to about 2 angstroms.

14. The capacitor structure of claim 9, wherein the support layer further includes the first metal and the second metal.

15. The capacitor structure of claim 9, wherein a portion of the lower electrode contacting the first interface pattern further includes the first metal.

16. The capacitor structure of claim 9, further comprising an interface oxide layer between the dielectric pattern and the upper electrode.

17. A semiconductor device, comprising:
an active pattern on a substrate;
a gate structure in an upper portion of the active pattern, the gate structure extending in a first direction substantially parallel to an upper surface of the substrate;
a bit line structure on a middle portion of the active pattern, the bit line structure extending in a second direction substantially parallel to the upper surface of the substrate and crossing the first direction;
a contact plug structure on each of opposite ends of the active pattern; and
a capacitor structure on the contact plug structure, the capacitor structure including:
a lower electrode on the substrate,
a support layer on a sidewall of the lower electrode, the support layer including an insulating material;
an interface structure including:
a first interface pattern on the sidewall of the lower electrode, the first interface pattern including a first metal, and
a second interface pattern including a first portion on an outer sidewall of the first interface pattern and a second portion on a surface of the support layer, the second interface pattern including an oxide of a second metal, and the second portion of the second interface pattern further including the first metal,
a dielectric pattern on the interface structure, and
an upper electrode on the dielectric pattern.

18. The capacitor structure of claim 17, wherein a thickness in a vertical direction of the second portion of the second interface pattern is greater than a thickness in a horizontal direction of the first portion of the second interface pattern, the vertical direction being substantially perpendicular to the upper surface of the substrate, and the horizontal direction being substantially parallel to the upper surface of the substrate.

19. The capacitor structure of claim 17, wherein the first metal includes scandium (Sc), yttrium (Y), titanium (Ti), vanadium (V), niobium (Nb), tantalum (Ta), chromium (Cr), molybdenum (Mo), tungsten (W), iron (Fe), ruthenium (Ru), osmium (Os), cobalt (Co), rhodium (Rh), iridium (Ir), boron (B) or tin (Sn).

20. The capacitor structure of claim 9, wherein the second metal includes a metal with four valance electrons or a metal with three valance electrons.
